(19) United States
(12) Patent Application Publication
(10) Pub. No.: US 2007/0099332 A1
(43) Pub. Date: May 3, 2007

(54) Chalcogenide PVD components and methods of formation

(75) Inventors: Janine K. Kardokus, Veradale, WA (US); Michael R. Pinter, Spokane, WA (US); Ravi Rastogi, Liberty Lake, WA (US); Diana L. Morales, Veradale, WA (US); Michael D. Payton, Spokane, WA (US)

Correspondence Address: WELLS ST. JOHN P.S., 601 W. FIRST AVENUE, SUITE 1300, SPOKANE, WA, 99201, US

(73) Assignee: Honeywell International Inc.

(21) Appl. No.: 11/598,177

(22) Filed: Nov. 9, 2006

Related U.S. Application Data
(63) Continuation-in-part of application No. 11/178,202, filed on Jul. 7, 2005.
(63) Continuation-in-part of application No. 11/230,071, filed on Sep. 19, 2005.

(51) Int. Cl. H01L 21/00

(52) U.S. Cl. 438/95

(57) ABSTRACT

A PVD component forming method includes identifying two or more solids having different compositions, homogeneously mixing particles of the solids using proportions which yield a bulk formula, consolidating the homogeneous particle mixture to obtain a rigid mass while applying pressure and using a temperature below the minimum temperature of melting or sublimation of the solids, and forming a PVD component including the mass. A chalcogenide PVD component includes a rigid mass containing a bonded homogeneous mixture of particles of two or more solids having different compositions, the mass having a microcomposite structure exhibiting a maximum feature size of 500 μm or less, and one or more of the solids containing a compound of two or more bulk formula elements. An alternative PVD component exhibits a uniform composition with less than 10% difference in atomic compositions from feature to feature.

### RELATED PATENT DATA

This patent is a continuation-in-part of U.S. patent application Ser. No. 11/178,202 filed Jul. 7, 2005 entitled “Chalcogenide PVD Components,” which is incorporated herein by reference. This patent is also a continuation-in-part of U.S. patent application Ser. No. 11/230,071 filed Sep. 19, 2005 entitled “Chalcogenide PVD Components and Methods of Formation,” which is herein incorporated by reference.

### TECHNICAL FIELD

The invention pertains to chalcogenide physical vapor deposition (PVD) components and chalcogenide PVD component forming methods.

### BACKGROUND OF THE INVENTION

Chalcogenide alloys are a class of materials known to transition from a resistive to a conductive state through a reversible phase change that may be activated with an electrical pulse or with a laser. A transition from a crystalline phase to an amorphous phase constitutes one example of such a phase change. The transition property allows scaling to 65 to 45 nanometer line widths and smaller for next generation DRAM technology. Chalcogenide alloys exhibiting the transition property often include 2 to 6 element combinations from Groups 11-16 of the IUPAC Periodic Table (also known respectively as Groups IB, IIB, IIIA, IVA, VA, and VIA). Examples include GeSe, AgSe, GeSbTe, GeSeTe, GeSbSeTe, TeGeSbS, and AgInSbTe, as well as other alloys, wherein such listing does not indicate empirical ratios of the elements. Interest also exists in using chalcogenide alloys for optical data storage and solar cell applications.

Technically speaking, “chalcogens” refers to all elements of Group 16, namely, O, S, Se, Te, and Po. Accordingly, a “chalcogenide” contains one or more of these elements. However, to date, no chalcogenide alloys have been identified that contain O or Po as the only chalcogen and exhibit the desired transition. Thus, in the context of phase change materials, the prior art sometimes uses “chalcogenide” to refer to compounds containing S, Se, and/or Te, excluding oxides that do not contain another chalcogen. Chalcogenide compounds can be made into physical vapor deposition (PVD) targets, which in turn can be used to deposit thin films of the phase change memory material onto silicon wafers. Although several methods of depositing thin films exist, PVD, including but not limited to sputtering, will likely remain as one of the lower cost and simpler deposition methods. Apparently then, it is desirable to provide chalcogenide PVD targets.

### BRIEF DESCRIPTION OF THE DRAWINGS

Preferred embodiments of the invention are described below with reference to the following accompanying drawings.

FIG. 1 is a flow chart depicting a PVD component forming method according to one aspect of the invention.

FIG. 2 is a flow chart depicting a conventional PVD component forming method.

FIG. 3 is a side view of an alloy casting apparatus according to one aspect of the invention.

FIG. 4 is a chart of DTA data for Ag₂Se produced by various methods.

FIGS. 5A and 5B are respectively a 100× optical micrograph and a 100× scanning electron microscope (SEM) image of consolidated Ge, Sb, and Te powders. FIG. 5C is a 2000× magnification of the FIG. 5B image.

FIGS. 6A and 6B are respectively a 100× optical micrograph and a 100× SEM image of consolidated GeTe and Sb₂Te₃ powders.

FIGS. 7A and 7B are respectively a 100× optical micrograph and a 100× SEM image of a cast, ground, and then consolidated Ge₂Sb₂Te₅ alloy.

FIGS. 8A and 8B are respectively a 400× optical micrograph and a 100× SEM image of a cast, ground, and then consolidated CuInSe₂ alloy.

FIGS. 9A and 9B are respectively a 400× optical micrograph and a 100× SEM image of a cast, ground, and then consolidated CuInGaSe₂ alloy.

### DETAILED DESCRIPTION OF THE PREFERRED EMBODIMENTS

In most PVD processes, the only significant deposition occurs from a target containing the desired material. However, in some PVD processes non-target components of the deposition apparatus may significantly contribute to deposition and thus contain the same material as the target. In the context of the present document, a PVD “component” is defined to include targets as well as other non-target components, such as ionization coils. Similarly, “PVD” is defined to include sputtering, evaporation, and ion plating as well as other physical vapor deposition methods known to those of ordinary skill.

Phase change memory research often involves identification of particular compositional formulations with two or more alloying elements. Unfortunately, composition control presents a difficulty in forming chalcogenide alloy PVD components. Generally, the elements of a given alloy may exhibit a wide range, in some cases more than 1,000° C., of melting or sublimation temperatures, wherein elements undergo phase changes between solid and liquid (melting) or solid and gas (sublimation). Processing may thus include solid to liquid and/or solid to gas phase changes. Processing may also include strongly exothermic reactions between elements, for example, between Ag/Se and between Ga/Se. The reactions and/or phase changes can segregate elements in the alloys and produce a solid containing a range of compositions.

Conventional attempts at controlling segregation include heating and rapid cooling in a sealed quartz ampoule to control outgassing of low melting or sublimating elements. Such attempts complicate processing and have only found success in forming some binary and some ternary compounds. Also, the alloy volume obtained from one ampoule is characteristically small compared to the alloy volume used in most sputtering targets. Alloys produced in multiple ampoules are often combined in a single target. Understandably, such complex fabrication methods might not be cost effective and/or compatible with existing semiconductor fabrication process flows and control systems, especially those involving four or more chalcogenide alloying elements.

Other fabrication technologies that might be explored include liquid phase epitaxy, chemical vapor deposition, or evaporation of multiple pure elements, but they may be prohibitively difficult to deposit chalcogenide alloys given the need for complex compositional control and the likely poor cost effectiveness. Atomic layer deposition presents another possibility, but stable, predictable precursors do not appear readily available for all elements of interest given the relative immaturity of such technology.

PVD of chalcogenide alloy films presents one of the few commercially practicable methods of forming a chalcogenide alloy composition. Even so, PVD component fabrication presents it own difficulties. Areas of concern include segregation between solid and liquid phase transitions, the hazardous nature of some elemental constituents of chalcogenide alloys, and the risk of contaminating conventional PVD component blanks fabricated in the same processing equipment as chalcogenide alloy component blanks. In addition, chalcogenide alloys tend to exhibit brittleness similar to gallium arsenide, creating difficulties with breakage during bonding, finishing, and general handling of the blank and component.

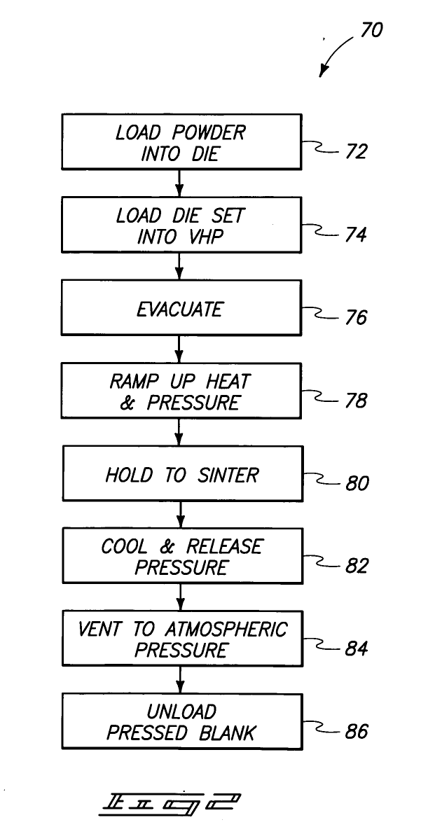

Vacuum hot pressing (VHP) represents a specific method conventionally used for producing a chalcogenide PVD component. Method 70 shown in FIG. 2 exemplifies possible steps in a VHP process. Step 72 involves loading a pre-made powder into a die set. The powder exhibits a bulk composition matching the desired composition of the component blank. In step 74, the die set may be loaded into a VHP apparatus. Following evacuation in step 76, heat and applied pressure ramping occurs during step 78. Sintering during step 80 occurs at a temperature below the onset of melting or sublimation, but at a high enough temperature and applied pressure to produce a solid mass of the powder particles. Cooling and releasing applied pressure in step 82 is followed by venting the VHP apparatus to atmospheric pressure in step 84. The pressed blank is unloaded in step 86.

Although a relatively simple method, observation indicates that VHP presents some difficulties. VHP apparatuses are typically designed for high temperature and applied pressure processing of refractory metal powder materials. A high risk of melting or sublimation exists in such systems where the chalcogenide composition includes low melting or sublimating elemental constituents, such as selenium or sulfur. Melting or sublimation during VHP may release hazardous vapors from the chalcogenide composition, contaminate and/or damage the VHP apparatus, and ruin the end product. Blanks with compositions that melt during VHP may stick to the die set and crack upon removal of the processed blank. Also, melted material that leaks past split sleeves of the die set can solidify during cooling, creating a wedge effect. The resulting high shear stress on the die set may cause significant failure.

Chalcogenide PVD components and forming methods according to:the aspects of the invention described herein minimize the indicated problems. In addition to a VHP, a hot isostatic press (HIP), cold isostatic press (CIP), etc. constitute acceptable consolidation apparatuses. Cold isostatic pressing may be followed by a sintering anneal. Typically, HIP or VHP processing includes sintering. Sintering, followed by cooling and releasing applied pressure, completes consolidation of the particle mixture. The removed blank may meet specifications for use as a PVD component or further processing known to those of ordinary skill may bring the blank into conformity with component specifications.

In one aspect of the invention, a chalcogenide PVD component forming method includes selecting a bulk formula including three or more elements, at least one element being from the group consisting of S, Se, and Te. The method includes identifying two or more solids having different compositions and, in combination, containing each bulk formula element. One or more of the solids contains a compound of two or more bulk formula elements. One of the solids exhibits a maximum temperature of melting or sublimation (maximum m/s temperature) among the solids. Another of the solids exhibits a minimum m/s temperature among the solids. The difference between the maximum and minimum m/s temperatures is no more than 500° C. The method includes homogeneously mixing particles of the solids using proportions which yield the bulk formula. The homogeneous particle mixture is consolidated to obtain a rigid mass while applying pressure and using a temperature below the minimum m/s temperature. A PVD component is then formed including the mass.

By way of example, the compound may be a congruently melting line compound, an incongruently melting compound, an alloy, or some other compound, as further discussed in detail below. The bulk formula may include three or more elements selected from the group consisting of metals and semimetals in Groups 11-16 of the IUPAC Periodic Table. Many of the presently identified advantageous chalcogenides consist of metals and semimetals in Groups 13-16. Semimetals in Groups 11-16 include boron, silicon, arsenic, selenium, and tellurium. Metals in Groups 11-16 include copper, silver, gold, zinc, cadmium, mercury, aluminum, gallium, indium, thallium, germanium, tin, lead, antimony, and bismuth.

Also, by way of example, the solids may, in combination, consist of each bulk formula element, such that the solids do not introduce any elements other than those in the bulk formula. Understandably, this is not to say that minor impurities are absent from the solids. The solids may be at least 99.9% pure with regard to the bulk formula elements, preferably 99.99% pure or as much as 99.9999% pure. One or more of the solids may consist of an elemental constituent. Two or more of the solids may each consist of a different binary or ternary compound. The particle mixture may be a powder. The particles may have a size of 300 micrometers (μm) (50 mesh) or smaller or, more advantageously, 44 μm (325 mesh) or smaller. The average size of the 300 μm or smaller particles may be 50 μm or smaller. Normally, a mix of particle sizes is expected and may assist in densification during consolidation.

Accordingly, a variety of options exist for the composition of the solids. However, by providing one of the solids as containing a compound, the typical large difference between the maximum and minimum m/s temperatures may be reduced to no more than 500° C. Reduction of the temperature difference may occur because the minimum m/s temperature is greater than a m/s temperature of one or more element of the compound. Instead, or in addition, reduction of the temperature difference may occur because the maximum m/s temperature may be less than a m/s temperature of one or more element of the compound.

That is, the compound may include the lowest melting or sublimating and/or the highest melting or sublimating element and may exhibit a respectively higher or lower m/s temperature in comparison to the element that the compound incorporates. Consequently, the described selection of a bulk formula, identification of two or more solids, and selection of certain compounds for incorporation into the solids has the potential to ease processing difficulties in forming a chalcogenide PVD component. The discussion below presents additional considerations that may be useful in further enhancing a component forming method.

As indicated, consolidating the particle mixture may use a temperature below the minimum m/s temperature. The consolidation may occur in an inert atmosphere. Instead, or in addition, the consolidation may occur under a vacuum of 0.5 atmosphere (atm) or less. The solids may exhibit stability up to the minimum m/s temperature and down to a vacuum pressure of 1×10⁻⁵ Torr or less. That is, “stable” solids do not undergo reactive changes, outgas, segregate, etc. or otherwise change in composition or reduce the homogeneity of the particle mixture. Generally, congruently melting line compounds provide such characteristics. However, other methods exist, and are described herein, for producing compounds that are not congruently melting line compounds and yet are stable.

In addition to consolidating at a temperature below the minimum m/s temperature of solids in the particle mixture, the consolidation temperature may be selected to be at least two-thirds of the maximum m/s temperature on the absolute temperature scale for reasons discussed in further detail below. The consolidating may be effective to accomplish solid state sintering of particles in the mixture. By definition, “solid state sintering” excludes sintering processes that allow melting or sublimation of solids. Solid state sintering constitutes one technique capable of producing a rigid mass suitable for inclusion in a PVD component. Further, where desired, other methods are capable of transforming the rigid mass so as to exhibit the bulk formula as a uniform composition with less compositional variability than existed from particle to particle in the particle mixture.

Consolidation may produce a rigid mass having microcomposite structure. Generally speaking, a composite structure is made up of distinctly different components, typically held together by a matrix. In a microcomposite structure, the distinct components are all very small with no particular component identifiable as a matrix. Indeed, all of the components may be structurally equivalent, as in the case of a particle mixture consolidated to obtain a rigid mass, which has no matrix. Instead, all of the components are particles.

Even so, since the rigid mass thus obtained contains distinct components, one would expect compositional variability in the rigid mass to be the same from feature to feature, that is, from particle to particle, for the microcomposite as existed in the particle mixture before consolidation. For example, depending upon differences in particle compositions, a microcomposite may exhibit more than 10% difference in atomic compositions from feature to feature. Of course, melting or sublimation of select elements during consolidation may upset the expectation of compositional variability remaining the same.

The described selection of solids, compounds, and/or elements along with prolonging application of described temperature and applied pressure conditions may allow a transition from a microcomposite structure to a structure that exhibits a uniform, essentially single, composition throughout the mass. Process times to accomplish the transition may vary depending upon the elemental constituents, compounds, particle sizes, etc. Essentially, it is believed that some or all of the compounds and/or elemental constituents migrate, diffuse, or otherwise relocate in the rigid mass and reduce compositional variability. Original particle boundaries may or may not remain. Using the teachings herein, those of ordinary skill may determine whether the transition occurred using known inspection techniques.

The rigid mass may thus exhibit the bulk formula as a uniform composition with less compositional variability than existed from particle to particle in the particle mixture. The compositional variability may further reduce with increasing process times. Accordingly, the rigid mass may exhibit a uniform composition with less than 10% difference in atomic compositions from feature to feature, regardless of compositional variability in the particle mixture. For practical purposes associated with PVD, there may be only minor performance differences between a target having a microcomposite structure and a target formed from a single pure compound. Accordingly, even less difference may exist between a microcomposite target transformed to exhibit less compositional variability and a target formed from a single pure compound.

VHP and HIP have proven successful in creating the described microcomposite or uniform composition. Formation of the PVD component may further include adhesive bonding, solder bonding, diffusion bonding, brazing, and/or explosive bonding of the rigid mass to a PVD target backing plate. It is conceivable that bonding to the backing plate may occur during or after consolidation of the particle mixture.

The bulk formula may include an element that is not in Groups 11-16. However, the bulk formula may consist of elements selected from Groups 11-16. Some exemplary bulk formulas include: GeSbTe, GeSeTe, GeSbSeTe, TeGeSbS, AgInSbTe, and SbGeSeSTe, as well as others, wherein such listing does not indicate empirical ratios of the elements. Understandably, certain elements in the bulk formulas may be provided in greater or lesser abundance compared to relative amounts of the other elements depending on the intended use of the PVD component. The rigid mass may exhibit a density of at least 95% of theoretical density or, more advantageously, at least 99%. Although a minimum and a maximum are listed for the above described temperature, size, purity, and density ranges, it should be understood that more narrow included ranges may also be desirable, as supported elsewhere herein, and may be distinguishable from prior art.

The compound may be one of the following line compounds: GeSe, GeSe₂, GeS, GeS₂, GeTe, Sb₂Se₃, Sb₂S₃, and Sb₂Te₃. In the context of the present document, “line compound” refers to particular compositions appearing in solid-liquid phase diagrams as congruently melting compositions. Such compounds are also referred to in the art as “intermediate compounds.” For congruently melting line compounds, the liquid formed upon melting has the same composition as the solid from which it was formed. Other solid compositions appearing in a phase diagram typically melt incongruently so that the liquid formed upon melting has a composition different than the solid from which it was formed.

When forming a chalcogenide PVD component, a particle mixture containing at least one element selected from the group consisting of S, Se, and Te may contain low and high melting or sublimating elements, creating a range of phase change points so large that processing becomes difficult. As the number of different elements increases to three or more, especially to five or more, the difficulty associated with mixed low and high melting or sublimating elements may similarly increase. In the discussion above, processing the particle mixture to form a rigid mass suitable to be used as a PVD component can melt or sublimate the low melting or sublimating elements.

The melted elements can produce strong exothermic reactions, outgas, segregate into melt regions exhibiting a composition different from regions of particle mixture that did not melt, sublimate to produce gaps in the particle mixture, and/or create other manufacturing difficulties. Such non-uniformities in PVD components may produce poor compositional control in the deposited thin films. The presence or absence of melt regions and/or sublimation gaps might be verifiable by comparing local composition variations to bulk composition and/or by visual inspection techniques.

As stated above, one or more of the solids may contain a compound. By providing a low melting or sublimating element in a line compound instead of as an elemental constituent, the minimum m/s temperature of the solids may be increased. A similar effect may be obtained by including a low melting or sublimating element in an incongruently melting or some other compound which nevertheless exhibits a higher m/s temperature than the low melting or sublimating element. By providing the low melting or sublimating element in one of these or another pre-reacted state, less risk exists of manufacturing difficulties.

Forming the rigid mass containing the particle mixture might include subjecting the mixture to a temperature close to the melting or sublimation point of the compound. However, even if a line compound melts, the liquid produced will exhibit the same composition as the solid from which is was formed and will be pre-reacted to avoid reaction with other compounds or elemental constituents. If an incongruently melting compound melts, then the liquid composition may differ somewhat from the solid composition from which the liquid was formed. However, the components could still be pre-reacted to avoid a sudden release of heat. Thus, the various compounds may minimize segregation and exothermic reactions in the PVD component.

The temperature selected for forming the rigid mass might be partially determined by the maximum m/s temperature of the particle mixture. Generally speaking, the greatest densification occurs at sintering temperatures as close a possible to a maximum m/s temperature of a particle mixture. As stated, the particle mixture may be selected to exhibit a maximum m/s temperature that is less than a m/s temperature of one or more element in the compound. By providing a high melting or sublimating element in the compound, instead of as an elemental constituent, the maximum m/s temperature of the particle mixture may decrease so that it is less than the m/s temperature of the highest melting or sublimating element. Decreasing the maximum m/s temperature may allow lowering of a temperature selected for forming the rigid mass. At lower process temperatures, less risk may exist for melting or sublimating other constituents of a particle mixture. Accordingly, aspects of the invention provide for narrowing the temperature range of melting or sublimation of a particle mixture from the low melting or sublimating side, the high melting or sublimating side, or both.

For SbGeSeSTe in the list above, Table 1 shows that Se and S exhibit respective melting points of 217° C. and 115° C. As pure elements, Ge and S have a melting point difference of 822° C. If an attempt were made to mix all five elements and melt them at the same time, the S would vaporize well before the Ge became warm enough to begin reacting with the other elements. If S is instead provided as a line compound with S₃Sb₂, and Se is provided as a line compound with GeSe and Sb₂Se₃, then the minimum melting point increases to that of Te, namely, 449.5° C. Table 2 shows the melting points of the line compounds.

Thus, significant advantage results from using compounds containing low melting or sublimating elements where the compound exhibits a higher m/s temperature. Table 1 shows that Ge exhibits a melting point of 937° C. If Ge is provided as a line compound with GeSe, then the maximum melting point decreases to that of GeSe, namely, 660° C. Table 2 shows the melting points of the line compound. Thus, significant advantage also results from using compounds containing high melting or sublimating elements where the compound exhibits a lower m/s temperature. Narrowing the range of m/s temperatures and operating particle consolidation methods at close to the minimum m/s temperature may improve densification during the consolidation process since the operating temperature becomes closer to the maximum m/s temperature.

Given the stability of the particle mixture described above as containing a compound, a wider variety of consolidation techniques might be suitable for forming the rigid mass containing the particle mixture. The stability may reduce some of the negative impacts of melting. However, a desire may nevertheless exist in many circumstances to form the rigid mass without creating melt regions or sublimation gaps. With the stated results as the goal, consolidation techniques may be selected that maximize densification of the particle mixture to obtain a rigid mass by drawing nearer to the point of creating melt regions since the negative effect of unintentionally melting may be less. Potential negative effects become less likely when fewer elements are provided as elemental constituents and more elements are provided in compounds.

In the context of the present document, stability may improve by providing a compound with pre-reacted elements as the lowest melting or sublimating constituent. Stability may further improve if any elemental constituents have a m/s temperature that is significantly greater than the minimum m/s temperature of the particle mixture. In this manner, approaching the minimum m/s temperature only risks melting or sublimating pre-reacted elements without risking melting or sublimating an element that may subsequently react with high energy release in the particle mixture.

A further advantage of aspects of the invention includes the ability to process a larger volume exhibiting a particular bulk formula, thus enabling manufacture of larger PVD components from a single batch of material. Such advantage may be contrasted with the process of collecting material from multiple quartz ampoules to provide a sufficient volume. Large sputtering targets are typically greater than 13.8 inches (in.) in diameter (greater than 150 square in.). The ability to make a large chalcogenide target containing three or more elements with accurate and uniform compositional control in both the target and the final deposited film on a substrate has not previously been realized. It is especially significant that such large targets may be a single-piece rigid mass exhibiting the desired bulk formula.

It is conceivable that single-piece targets with a surface area as high as 3,680 square in. exposed during PVD may be manufactured within such specifications. The described single-piece targets can accommodate silicon wafer substrates ranging in size from 100 millimeters (mm) to 450 mm in diameter and flat panel displays or solar cell substrates (glass or plastic) as large as 1.1 meters by 2 meters. Larger targets could be made by arranging multiple targets together as tiles in a multiple-piece target. Aspects of the invention greatly improve manufacturing efficiency and yield associated with making single-piece targets of such large size.

The chalcogenide PVD component forming methods may include synthesizing the one or more solids containing a compound of two or more bulk elements. Alternatively, the solids or compounds may be obtained from a commercial source. Synthesis methods may allow complete reaction of the most volatile, lowest melting or sublimating, and/or highest melting or sublimating elemental constituents to produce compounds exhibiting the stabilities described herein. It is conceivable that the compounds might react and/or diffuse together, however, compounds may be selected that do not react in a strong exothermic manner or with other negative effects.

Possible synthesis methods include casting and thermal kinetic synthesis (including sonochemical synthesis), as described herein, and other methods, including modifications of the disclosed methods. Possible other methods include casting using rapid solidification, mechanical alloying or ball milling without the addition of heat, or chemical precipitation of compounds from solutions containing the bulk formula elements. Such other methods may be performed according to the knowledge of those of ordinary skill. However, chalcogenide compound synthesis methods described herein, which are not previously known, possess advantages over the known alternatives and modifications thereof.

Compounds included in a given PVD component might be obtained using different synthesis methods since the advantage of one synthesis method over another may depend upon the elements combined. After synthesizing a compound containing two or more bulk formula elements, the formation of alloyed particles containing the compounds may include reducing particle size. A suitable particle size may be obtained using a manual or automatic mortar and pestle, jet milling, ball milling, roller milling, hammer milling, and/or crushing, grinding, or pulverizing machines. Size control of particles may be accomplished by sieving, cyclonic separation, or other particle classification methods.

Homogeneously mixing particles may be accomplished using conventional techniques such as V-blending, jar milling, cyclonic mixing, and/or fluidized bed mixing, among others. After consolidation of the particle mixture, a PVD component may be processed to its final configuration including, bonding to a backing plate, milling, lathe turning, grinding, etc. as known to those of ordinary skill.

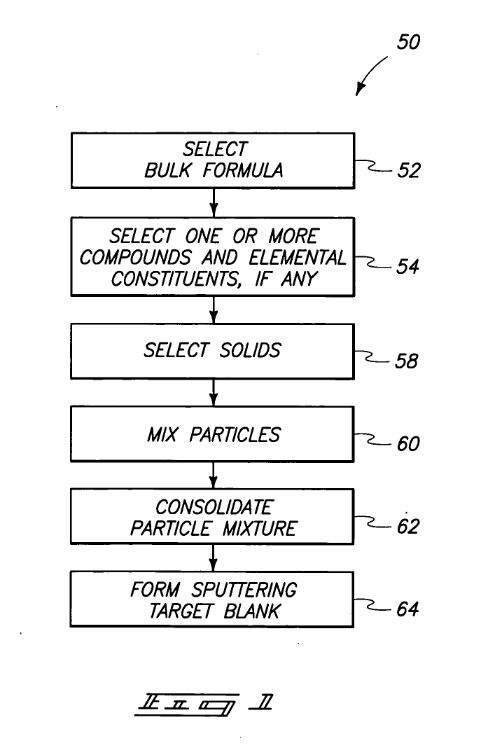

Method 50 shown in FIG. 1 provides some exemplary features of the aspects of the invention. The desired bulk formula is selected in step 52 and, in step 54 appropriate compounds and elemental constituents, if any are identified. A study of m/s temperatures of the compounds and elements may be used to reveal low and/or high melting or sublimating elements and possible compounds in which the elements may be included to raise the minimum and/or lower the maximum m/s temperature. Proportions of the compounds and elemental constituents, if any, may be determined to achieve the bulk formula selected in step 52. The discussion of Table 1-3 below provides more detail in this regard.

Once the compounds and elemental constituents, if any, along with their respective proportions are determined, selection of solids containing the desired materials occurs in step 58. The selected solids might be commercially available or method 50 could include preparing them according to known methods or methods disclosed herein. If solids are used that each consist only of one compound or elemental constituent, then the previous determination of mass proportions for such compounds and elemental constituents will match the mass proportions for the selected solids. However, a desire may exist to use solids that contain multiple compounds and/or elemental constituents. In such case, proportions of the solids which yield the selected bulk formula may be determined and may differ from the proportions determined for the individual compounds and elemental constituents.

Particles of the selected solids may be mixed in step 60. Typically, a desire exists for a PVD component to provide uniform deposition of a film exhibiting the selected bulk formula. Accordingly, homogeneous mixing of particles facilitates forming a homogeneous PVD component and meeting deposition specifications for the thin film. Powder blenders and other apparatus known to those of ordinary skill may be used to homogeneously mix particles. The particles may be powders and exhibit the particle size ranges discussed herein. Consolidation techniques such as described herein may be used in step 62 to form the rigid mass. To the extent that the particle consolidation does not directly produce a sputtering target blank or other PVD component within specifications, further processing may occur in step 64 to finish the target blank or component.

Aspects of the invention also include chalcogenide PVD components. In one aspect of the invention, a chalcogenide PVD component includes a rigid mass exhibiting a bulk formula including three or more elements, at least one element being from the group consisting of S, Se, and Te, and containing a bonded homogeneous mixture of particles of two or more solids having different compositions. The mass has a microcomposite structure exhibiting a maximum feature size of 500 μm or less. The two or more solids, in combination, contain each bulk formula element and one or more of the solids contain a compound of two or more bulk formula elements. In the context of the present document, features used to measure the feature size include crystalline grains, lamellae, particles, and regions of amorphous material with identifiable boundaries.

By way of example, the mass may consist of the particle mixture. Also, the mass may have a PVD exposure area of greater than 150 square in. For each element, the bulk formula may be within 5% of a composition of a PVD film deposited using the mass. The mass may be at least 99.9% pure with regard to the bulk formula elements. The features exhibiting a maximum size of 500 μm or less in the mass may exhibit an average feature size of 150 μm or less. As a further advantage, the maximum feature size may be 50 μm or less for improved sputtering performance, with 10 μm or less performing better still. The mass may exhibit stability down to a vacuum pressure of 1×10⁻⁵ Torr or less.

At least 10 volume % (vol %) of the mass may have a crystalline microstructure. Crystalline microstructure lends mechanical strength to the rigid mass and allows subsequent processing to a PVD component with a minimum of breakage and yield loss. In addition, crystalline microstructures tend to exhibit increased electrical and thermal conductivity in comparison to amorphous structures. The improved conductivities generally provide improved PVD characteristics in comparison to more electrically and/or thermally insulating amorphous microstructures. Often, complex chalcogenide bulk formulas tend to yield a mass favoring amorphous microstructures. Accordingly, obtaining a crystalline microstructure in 100 vol % or some other targeted portion of the mass can be challenging. Control of crystalline content and even obtaining 100 vol % crystalline microstructure may be accomplished as taught in U.S. patent application Ser. No. 11/230,071 filed Sep. 19, 2005 entitled “Chalcogenide PVD Components and Methods of Formation,” which is herein incorporated by reference as a priority application.

In another aspect of the invention, a chalcogenide PVD component includes a PVD target blank exhibiting a bulk formula including three or more elements, at least one element being from the group consisting of S, Se, and Te, and consisting of a bonded homogeneous mixture of particles of two or more solids having different compositions. The blank has a PVD exposure area of greater than 150 square in. The blank has a microcomposite structure exhibiting a maximum feature size of 50 μm or less and 100 vol % of the blank has a crystalline microstructure. The blank exhibits stability down to a vacuum pressure of 1×10⁻⁵ Torr or less. The two or more solids, in combination, consist of each bulk formula element and two or more of the solids each consist of a different binary or ternary compound of bulk formula elements. A backing plate is bonded to the target blank.

As indicated above, a microcomposite structure may be transformed to a uniform composition. Hence, in a further aspect of the invention, the rigid mass contains a homogeneous mixture of a compound of two or more bulk formula elements and one or more elemental constituent of the bulk formula and/or one or more additional compound of two or more bulk formula elements. The mass exhibits a maximum feature size of 500 μm or less. The mixture contains each bulk formula element and exhibits a uniform composition with less than 10% difference in atomic compositions from feature to feature.

By way of example, the mass may consist of the mixture. Also, the mass may have a PVD exposure area of greater than 150 square in. The mass may be at least 99.9% pure with regard to the bulk formula element. The maximum feature size may be 50 μm or less. The mass may exhibit an average feature size of 150 μm or less. The mass may exhibit stability down to a vacuum pressure of 1×10⁻⁵ Torr or less. At least 10 vol % of the mass may have a crystalline microstructure or, more advantageously, 100 vol %.

In a still further aspect of the invention, a chalcogenide PVD component includes a PVD target blank exhibiting a bulk formula including three or more elements, at least one element being from the group consisting of S, Se, and Te. The blank contains a homogeneous mixture of two or more different binary or ternary compounds of bulk formula elements. The blank has a PVD exposure area of greater than 150 square in., the blank exhibits a maximum feature size of 50 μm or less, 100 vol % of the blank has a crystalline microstructure, and the blank exhibits stability down to a vacuum pressure of 1×10⁻⁵Torr or less. The mixture consists of each bulk formula element and exhibits a uniform composition with less than 10% difference in atomic compositions from feature to feature. A backing plate is bonded to the target blank.

Table 1 shows a hypothetical example of a five-element formula for a chalcogenide PVD component. Using the desired atomic % (at. %) and the atomic weight (at. wt.) of each element, the required mass of each element may be calculated and is shown in Table 1. Table 1 also shows that, aside from selenium and sulfur, the range of m/s temperatures extends from 450° C. to 937° C. With selenium and sulfur melting at 217 and 115° C., respectively, adequate sintering of particles consisting of elemental constituents listed in Table 1 may be difficult without incurring significant manufacturing problems such as segregation, exothermic reactions, etc. Table 2 lists known binary line compounds for elements from Table 1. Additional pertinent line compounds or other compounds may exist. Noticeably, the compounds listed all exhibit melting points much higher than the selenium and sulfur melting points. Also, the line compounds listed all exhibit melting points much lower than the germanium melting point.

TABLE 1

| Element | At. % | At. Wt. | Gram/Mol | MP (° C.) |
|---|---|---|---|---|
| Sb | 15 | 121.76 | 18.26 | 630.74 |
| Ge | 15 | 72.64 | 10.90 | 937.4 |
| Se | 30 | 78.96 | 23.69 | 217 |
| S | 20 | 32.065 | 6.41 | 115.21 |
| Te | 20 | 127.6 | 25.52 | 449.5 |
| Total | 100 | | 84.78 | |

TABLE 2

| Compounds | At. % A element | At. % B element | MP (° C.) |
|---|---|---|---|
| GeSe | 50 | 50 | 660 |
| GeSe₂ | 33.3 | 66.7 | 742 |
| GeS | 50 | 50 | 665 |
| GeS₂ | 33.3 | 66.7 | 840 |
| GeTe | 50 | 50 | 724 |
| S₃Sb₂ | 60 | 40 | 550 |
| Sb₂Se₃ | 40 | 60 | 590 |
| Sb₂Te₃ | 40 | 60 | 618 |

As may be appreciated, the desired bulk formula may be obtained by selecting certain compounds in appropriate mass proportions. Depending upon the selections, the compounds may raise the minimum m/s temperature and/or lower the maximum m/s temperature. Table 3 lists three exemplary line compounds and another compound, SeTe, which is a continuous solid solution of the composition stated in Table 3. Table 3 lists the mass of individual elements contributed from the total mass of each of the four compounds. The total contributed mass of each element matches the required mass listed in Table 1 to produce the desired at. % of each element.

TABLE 3

| | | | | Mass (gm/mol) | | | | | |
|---|---|---|---|---|---|---|---|---|---|
| Cmpnd | At. % A | At. % B | MP ° C. | S | Se | Sb | Ge | Te | Total |
| GeSe | 50 | 50 | 660 | | 11.84 | | 10.90 | | 22.74 |
| Sb₂Se₃ | 40 | 60 | 690 | | 1.97 | 2.03 | | | 4.00 |
| S₃Sb₂ | 60 | 40 | 550 | 6.41 | | 16.23 | | | 22.65 |
| SeTe* | 38.5 | 61.5 | 270 | | 9.87 | | | 25.52 | 35.39 |

| | | | | | | |
|---|---|---|---|---|---|---|
| Total | 6.41 | 23.69 | 18.26 | 10.90 | 25.52 | 84.78 |

*Not a line compound

Table 3 lists a SeTe compound containing 38.5 at. % Se and 61.5 at. % Te. A 50 at. %/50 at. % SeTe compound exhibits a melting point of about 270° C. and the SeTe compound in Table 3 contains more Te which exhibits a melting point of 449.5° C. Thus, it is expected that the melting point of the SeTe in Table 3 will be higher. Accordingly, the temperature range of melting or sublimation for the compounds in Table 3 is less than 420° C. compared to 822° C. for the elements listed in Table 1. Consolidation of a particle mixture containing the compounds listed in Table 3 may thus proceed under more advantageous process conditions and achieve more advantageous properties in comparison to conventional chalcogenide PVD component forming methods.

Table 4 lists four exemplary compounds, only two of which are the same compounds listed in Table 3. However, the four compounds in Table 4 may be used to produce the same hypothetical five-element formula shown in Table 1. Notably, GeS is used in Table 4 instead of S₃Sb₂ used in Table 3 and the SeTe of Table 4 contains 11.1 at. % Se and 88.9 at. % Te. Although in a somewhat different format in comparison to Table 3, Table 4 lists the mass of individual elements contributed from the total mass of each of the four compounds. The total contributed mass of each element matches the required mass listed in Table 4 to produce 100 grams of a chalcogenide alloy with the desired at. % of each element. Tables 3 and 4 demonstrate that a variety of compounds may be used to obtain the same desired bulk formula.

TABLE 4
Binary Compound Blend for 5-Component Alloy

| | | | Melting Points ° C. | | | | |
|---|---|---|---|---|---|---|---|
| | | | 665 | 660 | 590 | 270 | |
| | | | Desired Composition | | | | |
| | | | GeS (g) | GeSe (g) | Sb2Se3 (g) | SeTe (g) | Total wt |
| Element | At % | g per 100 g | 12.35 | 12.72 | 42.50 | 32.43 | 100 |
| Sb | 0.15 | 21.54 | | | 21.54 | | 21.54 |
| Ge | 0.15 | 12.85 | 8.57 | 4.28 | | | 12.85 |
| Se | 0.3 | 27.94 | | 4.66 | 20.96 | 2.33 | 27.94 |
| S | 0.2 | 7.56 | 3.78 | 3.78 | | | 7.56 |
| Te | 0.2 | 30.10 | | | | 30.10 | 30.10 |
| | Total Wt | 100 | 12.35 | 12.72 | 42.50 | 32.43 | 100.00 |

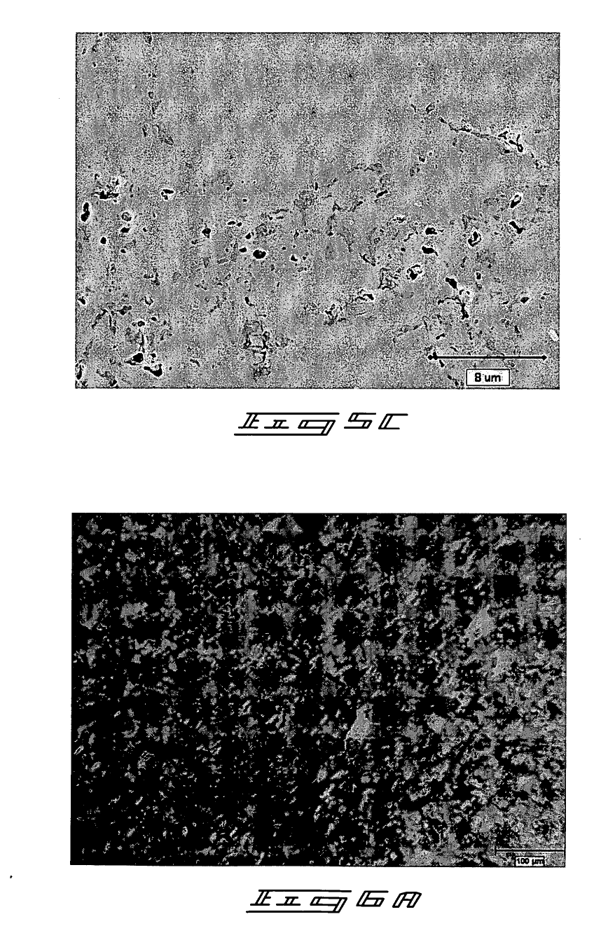

Table 5 lists two compounds which were obtained as solid particles and homogeneously mixed to produce a bulk formula of Ge₂Sb₂Te₅ using the proportions listed in Table 5. The homogeneous particle mixture was consolidated to obtain a rigid mass while applying pressure and using a temperature below 618° C., the minimum m/s temperature (i.e., for Sb₂Te₃). The consolidation transformed the particle mixture to exhibit the bulk formula as a uniform composition with less compositional variability. The mass exhibited a density of 6.37 grams/cubic centimeter (g/cc), which is slightly more than 100% of the published value of 6.30 g/cc. Differential thermal analysis (DTA), as widely known in the art, was used to ascertain that the mass exhibits a melting point of 620° C. No low melting or sublimating components were observed during DTA. FIGS. 6A and 6B respectively show a 100× optical micrograph and a 100× SEM image of the resulting rigid mass.

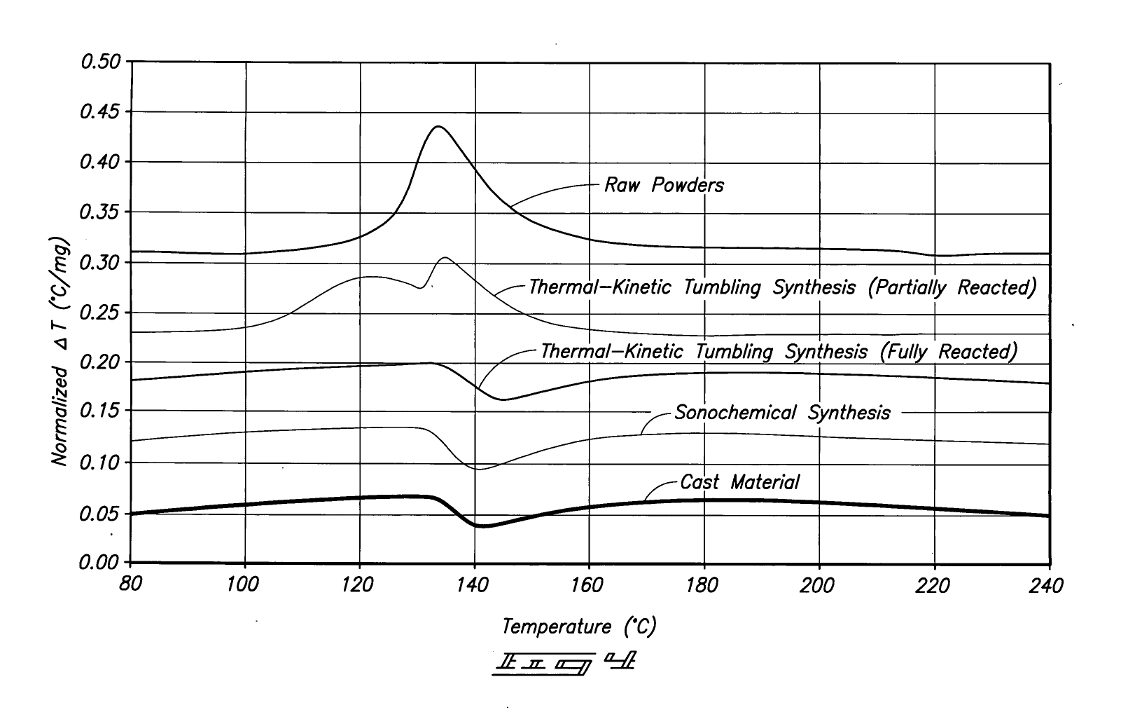

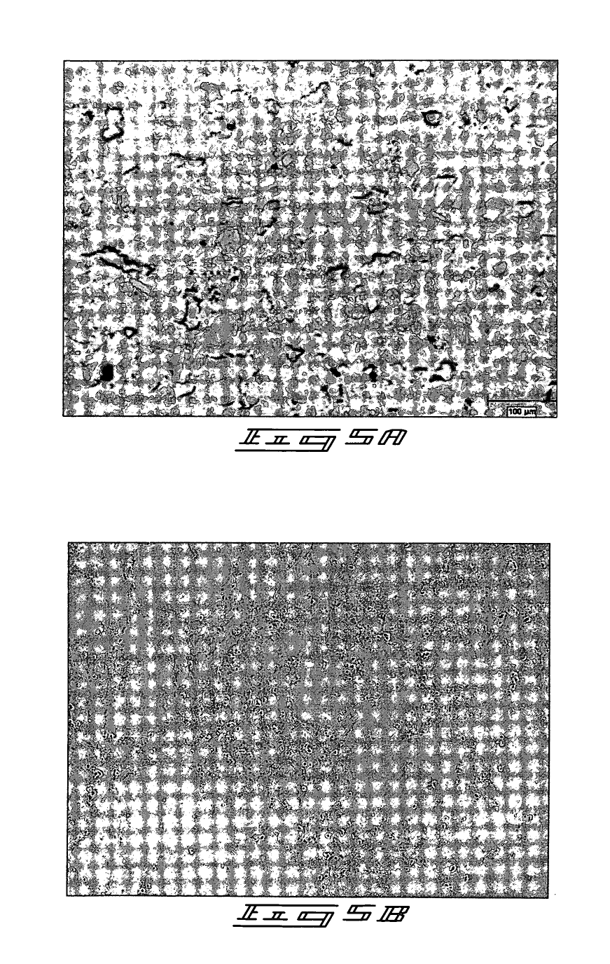

FIGS. 5A and 5B respectively show a 100× optical micrograph and a 100× SEM image of a rigid mass resulting from consolidation of elemental Ge, Sb, and Te powders. FIG. 5C is a 2000× magnification of the FIG. 5B image. The powders were homogeneously mixed and consolidated to obtain a rigid mass while applying pressure and using a temperature below 449.5° C., the melting point of Te and minimum m/s temperature of the particle mixture. The mass shown in FIGS. 5A-C may be contrasted with that of FIGS. 6A and 6B and shows a heterogeneous feature, namely, dark swirls identified as being Te rich. FIGS. 5B and 5C also show a higher incidence of porosity. The mass exhibited a density of 6.11 g/cc, which is 97.0% of the published value of 6.30 g/cc.

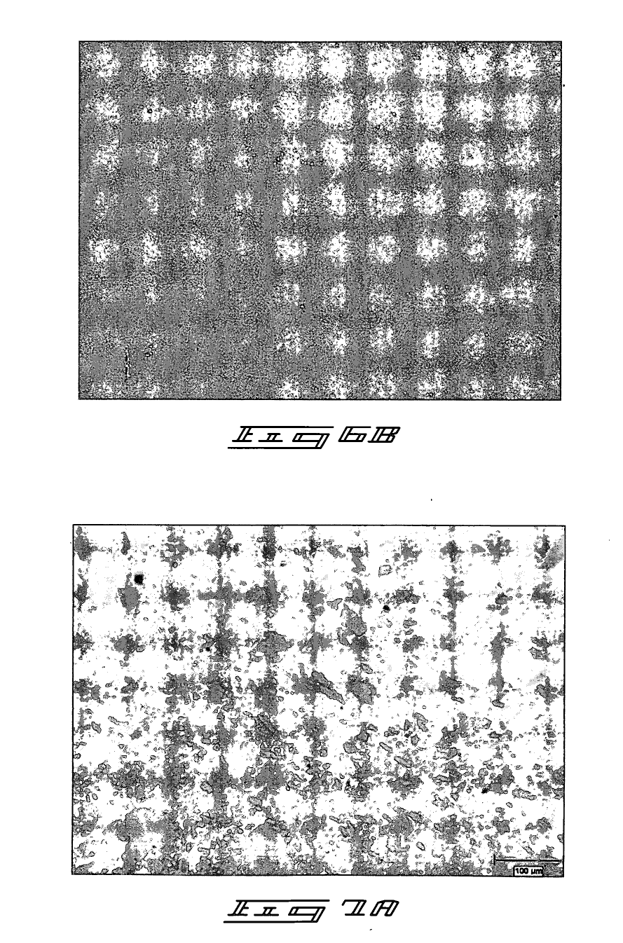

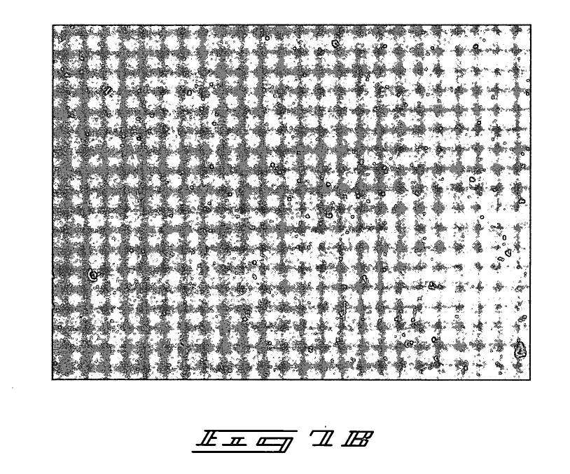

FIGS. 7A and 7B show the result of combining Ge, Sb, and Te powders in a graphite crucible, casting the powders to obtain a ternary compound with the formula Ge₂Sb₂Te₅, reducing the cast material to powder, and consolidating it to obtain a rigid mass. The mass in FIGS. 7A and 7B shows a similar morphology to that of FIGS. 6A and 6B. White specks in FIGS. 5B, 5C, 6B, and 7B are residual polishing media used to prepare samples for SEM. FIGS. 5A-7B demonstrate that aspects of the invention described herein are capable of overcoming previous difficulties associated with consolidating blended elemental powders. Aspects of the invention may obtain results similar to those produced from casting in quartz ampoules without the difficulties and constraints associated with quartz ampoule casting.

TABLE 5
Binary Compound Blend for Ge2Sb2Te5

| | | | Melting Points ° C. | | |
|---|---|---|---|---|---|
| | | | 724 | 618 | |
| | | | Desired Composition | | |
| | | | GeTe | Sb2Te3 | Total wt |
| Element | At % | g per 100 g | 39.00 | 61.00 | 100.00 |
| Ge | 22% | 14.14 | 14.14 | | 14.14 |
| Sb | 22% | 23.72 | | 23.72 | 23.72 |
| Te | 56% | 62.14 | 24.86 | 37.28 | 62.14 |
| | Total Wt | 100.00 | 39.00 | 61.00 | 100.00 |

Table 6 lists three compounds as a hypothetical example for producing CuInGaSe₂. Table 6 lists the mass of individual elements contributed from the total mass of each of the three compounds. The total contributed mass of each element matches the required mass listed in Table 6 to produce 100 grams of the chalcogenide alloy with the desired at. % of each element. The respective melting points of copper, selenium, indium, and gallium are 1,083, 217, 156, and 30° C. Since gallium is provided in the compound Ga₂Se₃ with a melting point of 1,005° C., the minimum m/s temperature is raised significantly to that of In₅₃Se₄₇. Including selenium and indium in the compound In₅₃Se₄₇ with a melting point of 630° C. establishes the new minimum m/s temperature of the compound mixture. Since copper is provided in the compound Cu₇In₃ with a melting point of 684° C., the maximum m/s temperature is also lowered to that of Ga₂Se₃. The difference between the maximum and minimum temperature is changed from 1,053° C. to 375° C.

TABLE 6
Binary Compound Blend for CuInGaSe2

| | | | Melting Points ° C. | | | |
|---|---|---|---|---|---|---|
| | | | 684 | 1005 | 630 | |
| | | | Desired Composition | | | |
| | | g per | Cu7In3 | Ga2Se3 | In53Se47 | Total wt |
| Element | At % | 100 g | 27.77 | 46.34 | 25.88 | 100 |
| Cu | 20% | 15.65 | 15.65 | | | 15.65 |
| In | 20% | 28.28 | 12.12 | | 16.16 | 28.28 |
| Ga | 20% | 17.17 | | 17.17 | | 17.17 |
| Se | 40% | 38.90 | | 29.17 | 9.72 | 38.90 |
| | Total Wt | 100.00 | 27.77 | 46.34 | 25.88 | 100.00 |

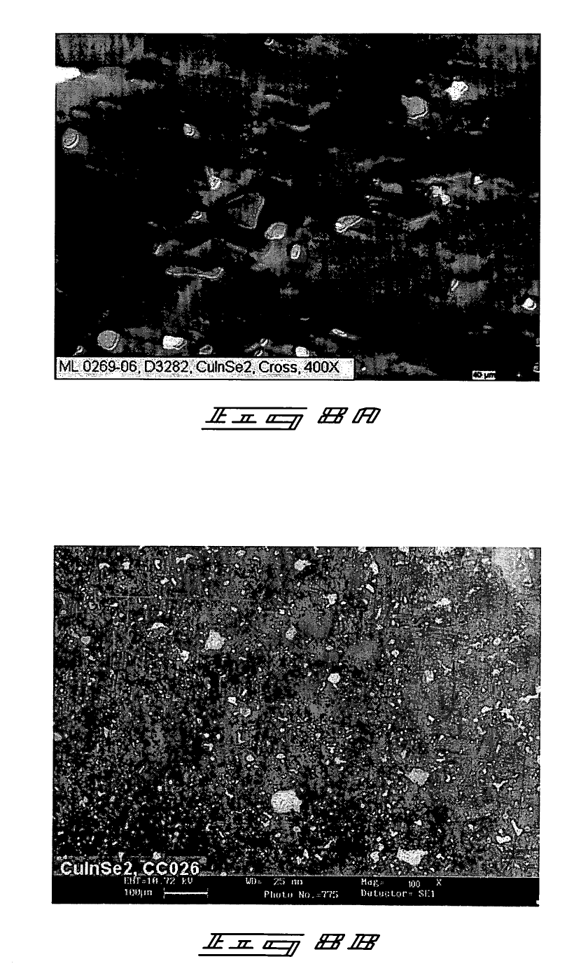

FIGS. 8A and 8B show the result of combining Cu, In, and Se powders in a graphite crucible and casting the powders at 95020 C. to obtain a melt with an approximate bulk formula of CuInSe₂. After solidification, the cast product had a visually homogeneous appearance and was reduced to particle sizes of less than 100 μm. DTA analysis of the powder from 200 to 1,000° C. did not reveal any strong exothermic reactions. The powder was vacuum hot pressed at 640° C. for 60 minutes to obtain a rigid mass with a brittle and also visually homogeneous appearance. The mass exhibited a density of 5.95 g/cc by the Archimedes method compared to a published value of 5.89 g/cc. A target blank was prepared from the rigid mass and is shown in the 400× optical micrograph of FIG. 8A to have a light colored second phase evenly distributed throughout a darker bulk phase. The second phase had a maximum feature size of 60 μm, but mostly less than 10 μm. Energy Dispersive X-ray Spectroscopy (EDS) revealed that the bulk phase shown in the 100× SEM image of FIG. 8B was In deficient and that the second phase was Cu—In rich, compared to the bulk formula. It was hypothesized that the second phase existed in the cast product, perhaps as a result of precipitates, even though not visually apparent. A sputtering target was formed from the blank and used to sputter a thin film having a composition within ±6 at. % for each element in the desired bulk formula.

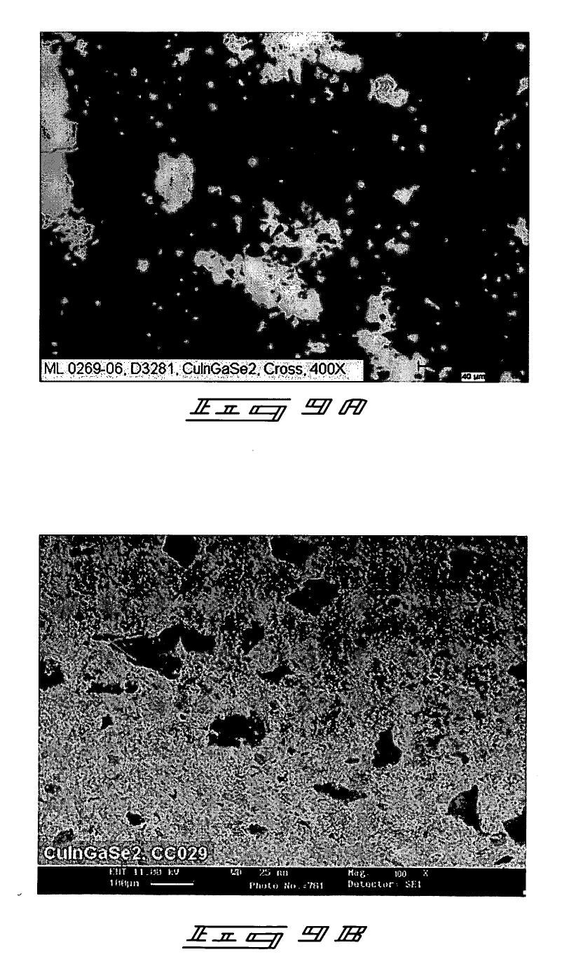

FIGS. 9A and 9B show the result of combining Cu, In, Ga, and Se powders in a graphite crucible and casting the powders at 850° C. to obtain a melt with an approximate bulk formula of CuInGaSe₂. After solidification, the cast product had a visually heterogeneous appearance with large regions of a light colored second phase in a darker bulk phase. Both phases were reduced to particle sizes of less than 100 μm. DTA analysis of the second phase powder, bulk phase powder, and both powders combined from 200 to 1,000° C. did not reveal any strong exothermic reactions for either phase or the combination thereof. The combined powders were vacuum hot pressed at 540° C. for 120 minutes to obtain a rigid mass with fine metallic-appearing flecks evenly distributed throughout the mass. The mass exhibited a density of 5.99 g/cc by the Archimedes method. No published value is known. A target blank was prepared from the rigid mass and is shown in the 400× optical micrograph of FIG. 9A. The second phase had a maximum feature size of 150 μm and a large variance in particle size due to particle agglomerates. Energy Dispersive X-ray Spectroscopy (EDS) revealed that the bulk phase shown in the 100× SEM image of FIG. 9B was In deficient and that the second phase was Cu—Ga rich, compared to the bulk formula. A sputtering target was formed from the blank and used to sputter a thin film having a composition within ±2 at. % for each element in the desired bulk formula.

Aspects of the invention also include synthesizing compounds, including chalcogenide and other compounds, that may be used in PVD component forming methods, as well as for possible other purposes. However, advantages associated with synthesis methods described herein are particularly significant in the context of forming PVD components. A chalcogenide compound synthesis method includes selecting a compound formula including two or more elements, at least one element being from the group consisting of S, Se, and Te. Using proportions which yield the compound formula, the method includes homogeneously mixing solid particles containing, in combination, each of the elements. The method also includes, during the mixing, imparting kinetic energy to the particle mixture, heating the particle mixture to a temperature below the minimum m/s temperature of the particles, alloying the elements, and forming alloyed particles containing the compound.

By way of example, the compound formula may consist of two elements. Also, one of the elements may exhibit a m/s temperature that is more than 500° C. above a m/s temperature exhibited by one other of the elements. One of the elements may exhibit the property of, upon melting, reacting exothermically with one other of the elements.

Since the synthesis method alloys the elements below the minimum m/s temperature of the particles, reaction of the elements may be induced without the generation of hazardous exotherms even though the temperature difference between m/s temperatures of the elements may be large. The imparting of kinetic energy may increase a reaction rate of the elements compared to not imparting kinetic energy. The heating to the temperature may increase a reaction rate of the elements compared to not heating. Individually, imparting of kinetic energy and heating to the temperature might not be sufficient to alloy the elements. However, combination of imparting kinetic energy at a raised temperature has proven effective in efficiently pre-reacting elemental constituents and forming alloyed particles containing the compound. As a result, the alloyed particles might not exhibit any normalized exotherms of more than 0.1° C. per milligram (° C./mg) during a DTA scan from 100 to 500° C. at a heating rate of 20° C. per minute. More advantageously, they do not exhibit any normalized exotherms of more than 0.01° C./mg.

The solid particles that are homogeneously mixed may have a size of 300 μm or less. Although various particle compositions are conceivable, the solid particles may include a first solid consisting of one of the elements and a second solid consisting of one other of the elements. A third solid consisting of yet another of the elements may be included. The solid particles may consist of each of the elements.

Various techniques and apparatuses are conceivable for imparting kinetic energy to and heating the particle mixture. As one example, the mixing and the imparting of kinetic energy may together comprise tumbling with inert media. Tumbling may occur in a variety of apparatuses, including those typically associated with ball milling and the like. The alloying may occur in an inert atmosphere. As another example, the mixing may include stirring the particles in a liquid and the imparting of kinetic energy may include applying ultrasonic energy.

Casting in quartz ampoules might be used to create a chalcogenide compound for subsequent use in consolidating particle mixtures. However, the described synthesis method involving imparting kinetic energy presents an opportunity for forming alloyed particles that are adequately stable for subsequent consolidation of particle mixtures on a much larger scale than the restrictive quartz ampoule casting processes.

In a further aspect of the invention, a chalcogenide compound synthesis method includes selecting a compound formula consisting of two or three elements, at least one element being from the group consisting of S, Se, and Te. One of the elements exhibits a m/s temperature that is more than 500° C. above a m/s temperature exhibited by one other of the elements. Using proportions which yield the compound formula, the method includes tumbling inert media in an inert atmosphere with solid particles consisting of, in combination, each of the elements. The solid particles have a size of 300 μm or less and include particles of one or more solids which each consist of one of the elements. The method includes, during the tumbling, heating the particle mixture to a temperature below the minimum m/s temperature of the particles, alloying the elements, and forming alloyed particles containing the compound.

Compound synthesis including both thermal and kinetic aspects (thermal kinetic synthesis) was previously accomplished according to the methods described above by combining 10 μm Ag flakes with 200 μm Se powder using proportions which yielded an Ag₂Se compound formula. Inert ceramic tumbling media was added with the particles in a suitable container to promote mixing and provide kinetic energy. The particle mixture was heated with a heat gun to 100° C. for 30 minutes while tumbling. In a second trial using the same amounts and conditions, the particles and media were heated to 75° C.

A DTA scan of the two products is shown in FIG. 4 with the 100° C. trial evidencing full reaction of the Ag and Se into alloyed particles by virtue of no exotherm. The 75° C. trial evidences only partial reaction by the significant exotherm. FIG. 4 also shows a cast, commercially available product for comparison to a material known to be fully reacted. For silver selenide, less than 150° C. may be suitable to obtain an effective reaction rate.

Sn₅₀Se₅₀ constitutes another compound amenable to the synthesis method. Both Ag₂Se and Sn₅₀Se₅₀ include Se, a known low melting, volatile and potentially unsafe element. CuSe is also a compound of interest. In the absence of fully alloying the Se, any residual elemental constituent may yield segregation and poor compositional control.

In addition to temperature and the use of media, other considerations include particle size and surface oxidation or coatings on the particles. Surface oxidation or coating may impede reaction rate and warrant avoiding such interference by employing careful handing and/or an inert atmosphere during application of kinetic energy. However, in the case of highly reactive elements, reaction rate may be beneficially controlled using surface oxidation or coatings to avoid exceeding safe or otherwise desirable reaction rate limits. Particle size has also been observed to influence reaction rate and the completeness of alloying. Tumbling containers may be non-reactive to the materials being used. The most suitable temperature, particle size, coatings, or revolutions per minute may vary depending upon the elemental constituents and/or compounds used. However, with knowledge of reactivities and specifications for alloying completeness, those of ordinary skill may use the parameters described herein to obtain safe processing conditions and suitable results.

Ultrasonic energy applied to a liquid containing the particle mixture may also be used to impart kinetic energy. Without being limited to a particular theory, it is believed that ultrasonic cavitation in the liquid accelerates particles together at supersonic speed while creating a high temperature transient within the cavitation bubble. Accompanied by heating, it is possible for the particle collisions to alloy the elements, forming alloyed particles containing a compound exhibiting a desired formula. Inclusion of a mild chelating agent in the liquid may assist in the chemical reaction by keeping chalcogenide atoms in solution.

Ag₂Se and Ge₂Sb₂Te₅ were successfully synthesized using elemental powders. The powders ranged in particles size from 100 mesh to 325 mesh and were weighed to provide proportions which yielded each of the compound formulas mentioned above. The powders were stirred into a 1:1 volume solution of 1 Molar NH₄OH (the mild chelating agent) and de-ionized water. After stirring at 650 revolutions per minute for 5 minutes, the liquid and powder mixture was heated to between 60 and 70° C. and then subjected to ultrasonic energy for 30 minutes. Frequency of the ultrasonic energy swept between 38.5 and 40.5 kiloHertz using 90 Watts of power. After settling, the alloyed powders were decanted, rinsed with de-ionized water, rinsed with methanol, filtered, and dried.

The alloyed particles produced the results shown in FIG. 4 upon DTA scanning. Notably, the product of sonochemical synthesis exhibited similar characteristics to those of the other fully reacted thermal kinetic synthesis product using tumbling. As thermal kinetic synthesis alternatives to the tumbling and sonochemical techniques exemplified herein, it is conceivable that other techniques for imparting kinetic energy and heating might be used to form alloyed particles containing compounds of desired chalcogenide formulas.

In another aspect of the invention, a chalcogenide compound synthesis method includes selecting a compound formula including two or more elements, at least one element being from the group consisting of S, Se, and Te. Using proportions which yield the compound formula, the method includes homogeneously mixing solid particles containing, in combination, each of the elements. The method also includes, under an inert atmosphere, melting the particle mixture in a heating vessel, removing the melt from the heating vessel, placing the melt in a quenching vessel, and solidifying the melt. The solidified melt is reduced to alloyed particles containing the compound.

By way of example, the compound formula may consist of two elements. One of the elements may exhibit a m/s temperature that is more than 500° C. above a m/s temperature exhibited by one other of the elements. One of the elements may exhibit the property of, upon melting, reacting exothermically with one other of the elements. The solid particles may include a first solid consisting of one of the elements and a second solid consisting of one other of the elements. The solid particles may consist of each of the elements.

Melting of the particle mixture may include heating at a rate of more than 3° C. per minute. The quenching vessel may include a collection pan having an actively cooled quench plate above a bottom of the collection pan. Placing the melt in the quenching vessel may include pouring the melt over the quench plate and collecting the solidified melt in the collection pan below the quench plate. The quenching vessel may instead include a casting mold exhibiting a thermal mass or active cooling, which cools the melt at an initial rate more than 100° C. per minute during solidification. The alloyed particles may be amorphous. The alloyed particles may exhibit no normalized exotherms of more than 0.1° C./mg during a DTA scan from 100 to 500° C. at a heating rate of 20° C. per minute.

Typical difficulties associated with casting of chalcogenide alloys, especially those alloys containing Se and/or S, include the outgassing of low melting, volatile elements and the segregating of components during cooling. The outgassing affects compositional control and may pose health risks. Segregation may create a heterogeneous product. Oxidation of elements in the cast alloy can also be a difficulty. Consequently, aspects of the invention include melting the particle mixture in a heating vessel in an inert atmosphere. The inert atmosphere helps minimize volatile constituent loss, minimize oxidation, and contain hazardous vapors.

The methods also include removing the melt from the heating vessel and placing the melt in a quenching vessel. Use of a separate quenching vessel assists in obtaining rapid solidification, which may help avoid segregation during cooling. Quickly heating the particle mixture to obtain a melt can also help reduce segregation since it minimizes the amount of time in which the initially homogeneously mixed solid particles may migrate into heterogeneous composition regions within the melt.

With a preference for an amorphous microstructure, little concern exists for meeting a specific heating and/or cooling profile over time to, for example, provide a crystalline microstructure. Instead, the amorphous solidified melt may be reduced to alloyed particles having sizes conducive to subsequent consolidation and processing to obtain a homogeneous rigid mass with 10 to 100 vol % crystalline microstructure, depending on specifications. Generally, amorphous chalcogenide alloys are brittle in nature and may be easily reduced to particles.

A further aspect of the invention includes an alloy casting apparatus with an enclosure, a heating vessel inside the enclosure, a heating mechanism thermally connected to the heating vessel, a flow controller, and a collection pan and an actively cooled quench plate inside the enclosure. The enclosure is configured to maintain an inert atmosphere during casting operations. The heating vessel has a bottom-pouring orifice and a pour actuator. The flow controller operates the pour actuator from outside the enclosure. The quench plate is positioned above a bottom of the collection pan and below the bottom-pouring orifice. As may be appreciated from the description above, the chalcogenide compound synthesis method that includes melting the particle mixture and placing the melt in a quenching vessel may be practiced in the alloy casting apparatus.

By way of example, the apparatus may further include a volatile component trap and a pump configured to purge the enclosure's atmosphere through the trap. Given the possibility of hazardous volatile components in chalcogenide casting, the volatile component trap may be an important safety measure. The heating mechanism may include induction heating coils around the vessel and insulation around the heating coils. Induction or resistance heating may be used to melt a chalcogenide particle mixture. The apparatus may further include a view port through the enclosure and configured to allow viewing and/or electronic imaging of melting operations. In addition or instead, the apparatus may further include a view port through the enclosure and configured to allow viewing and/or electronic imaging of pouring operations.

The apparatus may further include a charge vessel inside the enclosure and a charge controller. The charge vessel may be positioned to add a charge of material to the heating vessel and may be operated by the charge controller from outside the enclosure. Thus, in the event that processing specifications warrant adding a solid material after melting another solid material, temperature sensing devices, such as thermocouples, may indicate an appropriate time for adding a charge of material to the melt using the charge vessel and charge controller without opening the enclosure. If a view port for melting operations is provided, then a visual indication of a suitable time for adding additional material may be obtained.

Active cooling of the quench plate, for example, with water may provide rapid solidification. If a view port for pouring operations is provided, then a visual indication may be obtained regarding an appropriate coolant flow rate to provide the solidification effect desired. Also, given the variety of possible uses for the alloy casting apparatus, it may be configured to operate at up to 1500° C.

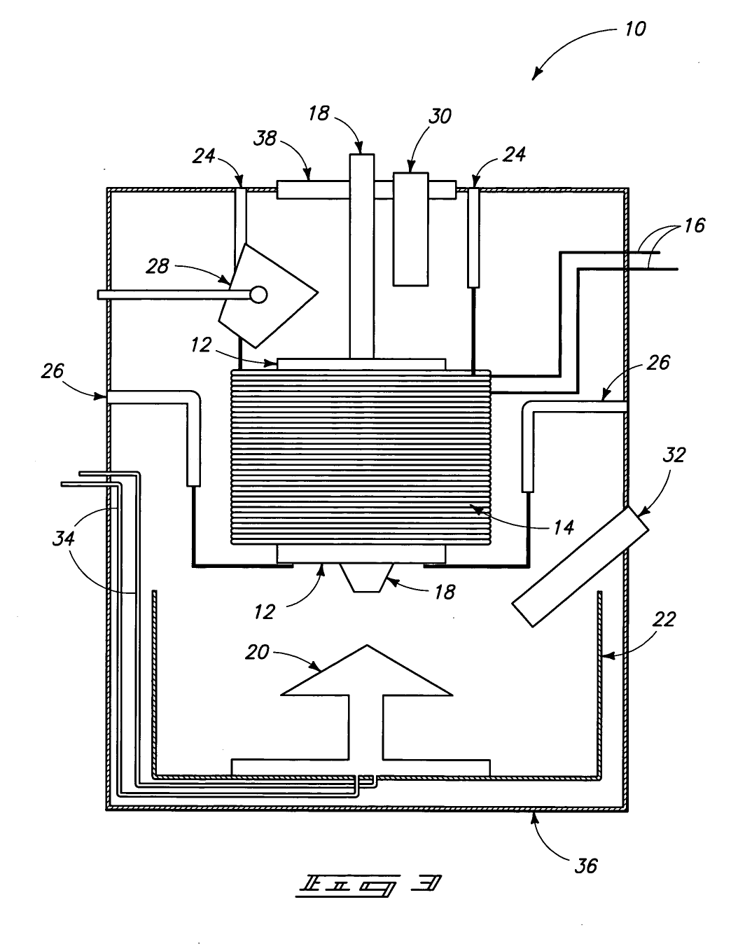

FIG. 3 shows a quench furnace 10 which includes a crucible 12 and crucible supports 26 within a vented enclosure 36. An induction coil 14 with coil leads 16 to a power source external of enclosure 36 wraps around crucible 12 and is supported by coil supports 24 within enclosure 36. Crucible 12 may have a cylindrical shape. Crucible 12 has a bottom-pouring orifice (not shown) in operable association with a flow actuator 18, as is conventional for bottom-pouring crucibles. As shown in FIG. 3, actuator 18 includes a handle that extends through access lid 38, allowing flow control of flow actuator 18 from outside enclosure 36. Access lid 38 also provides a camera port 30 in a position to view melting operations.

A charge vessel 28 is positioned to add a charge of material to crucible 12 using a handle that extends outside enclosure 36 to control addition of the charge. A quench plate 20 is provided in a collection pan 22 below the bottom-pouring orifice associated with flow actuator 18. Coolant lines 34 provide active cooling of quench plate 20 when used to quench a melt pouring from the orifice of crucible 12. A camera port 32 is positioned to allow a view of pouring operations. In the case of either camera port 30 or camera port 32, a variety of configurations are conceivable to allow electronic imaging and/or merely viewing operations.

The alloy casting apparatuses described herein configured to maintain an inert atmosphere and/or providing a vented enclosure may be evacuated, pressurized, or backfilled with inert gas. For example, argon or nitrogen may be used to control volatile constituents and/or avoid contamination or oxidation of the melt. The enclosure's vent may be closed during operations and merely used to purge the enclosure's atmosphere after operations cease. Alternatively, the vent actively removes the enclosure's atmosphere during operations. Even though significant advantages exist in using the alloy casting apparatus for forming chalcogenide alloys, other high purity alloys, such as master alloys of TiAl and CuAl, may be produced in the apparatus.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in. any of its forms or modifications within the proper scope of the appended claims appropriately interpreted in accordance with the doctrine of equivalents.

We claim:

1. A chalcogenide PVD component forming method comprising:
selecting a bulk formula including three or more elements, at least one element being from the group consisting of S, Se, and Te;
identifying two or more solids having different compositions and, in combination, containing each bulk formula element, one or more of the solids containing a compound of two or more bulk formula elements, one of the solids exhibiting a maximum temperature of melting or sublimation among the solids, another of the solids exhibiting a minimum temperature of melting or sublimation among the solids, and the difference between the maximum and minimum being no more than 500° C.;
homogeneously mixing particles of the solids using proportions which yield the bulk formula;
consolidating the homogeneous particle mixture to obtain a rigid mass while applying pressure and using a temperature below the minimum temperature of melting or sublimation; and
forming a PVD component including the mass.

2. The method of claim 1 wherein two or more of the solids each consist of a different binary or ternary compound.

3. The method of claim 1 wherein one or more of the solids consists of an elemental constituent.

4. The method of claim 1 wherein the consolidating occurs under a vacuum of 0.5 atm or less and the solids exhibit stability up to the minimum temperature of melting or sublimation and down to a vacuum pressure of 1×10⁻⁵ Torr or less.

5. The method of claim 1 wherein the consolidation temperature is at least two-thirds of the maximum temperature of melting or sublimation on the absolute temperature scale.

6. The method of claim 1 wherein the consolidating comprises vacuum hot pressing or hot isostatic pressing.

7. The method of claim 1 further comprising transforming the rigid mass to exhibit the bulk formula as a uniform composition with less compositional variability than existed from particle to particle in the homogeneous particle mixture.

8. The method of claim 1 wherein forming the PVD component comprises adhesive bonding, solder bonding, or diffusion bonding of the mass to a PVD target backing plate.

9. A chalcogenide PVD component forming method comprising:
selecting a bulk formula including three or more elements, at least one element being from the group consisting of S, Se, and Te;
identifying two or more solids having different compositions and, in combination, consisting of each bulk formula element, two or more of the solids each consisting of a different binary or ternary compound of bulk formula elements, one of the solids exhibiting a maximum temperature of melting or sublimation among the solids, another of the solids exhibiting a minimum temperature of melting or sublimation among the solids, and the difference between the maximum and minimum being no more than 500° C.;
homogeneously mixing particles of the solids using proportions which yield the bulk formula, the particles having a size of 44 μm or less;
consolidating the homogeneous particle mixture to obtain a sputtering target blank under a vacuum of 0.5 atm or less while applying pressure and using a temperature of at least two-thirds of the maximum temperature of melting or sublimation on the absolute temperature scale, but below the minimum temperature of melting or sublimation, the solids exhibiting stability up to their respective temperatures of melting or sublimation and down to a vacuum pressure of 1×10⁻⁵ Torr or less; and
forming a sputtering target including the blank bonded to a backing plate.

10. A chalcogenide PVD component comprising:
a rigid mass exhibiting a bulk formula including three or more elements, at least one element being from the group consisting of S, Se, and Te, and containing a bonded homogeneous mixture of particles of two or more solids having different compositions, the mass having a microcomposite structure exhibiting a maximum feature size of 500 μm or less; and
the two or more solids, in combination, containing each bulk formula element and one or more of the solids containing a compound of two or more bulk formula elements.

11. The component of claim 10 wherein the mass is a single piece and has a PVD exposure area of greater than 150 square in.

12. The component of claim 10 wherein one the solids exhibits a minimum temperature of melting or sublimation among the solids that is greater than a temperature of melting or sublimation of one or more element of the compound.

13. The component of claim 10 wherein one of the solids exhibits a maximum temperature of melting or sublimation among the solids that is less than a temperature of melting or sublimation of one or more element of the compound.

14. The component of claim 10 wherein, for each element, the bulk formula is within 5% of a composition of a PVD film deposited using the mass.

15. The component of claim 10 wherein the maximum feature size is 50 μm or less.

16. The component of claim 10 wherein the mass exhibits stability down to a vacuum pressure of 1×10⁻⁵ Torr or less.

17. The component of claim 10 wherein at least 10 vol % of the mass has a crystalline microstructure.

18. The component of claim 10 wherein the three or more elements are Cu, In, and Se or Cu, In, Ga, and Se.

19. The component of claim 18 wherein the bulk formula is CuInSe₂ or CuInGaSe₂.

20. A chalcogenide PVD component comprising:
a single-piece PVD target blank exhibiting a bulk formula including three or more elements, at least one element being from the group consisting of S, Se, and Te, and consisting of a bonded homogeneous mixture of particles of two or more solids having different compositions, the blank having a PVD exposure area of greater than 150 square in., the blank having a microcomposite structure exhibiting a maximum feature size of 50 μm or less, 100 vol % of the blank having a crystalline microstructure, and the blank exhibiting stability down to a vacuum pressure of 1×10⁻⁵ Torr or less;
the two or more solids, in combination, consisting of each bulk formula element and two or more of the solids each consisting of a different binary or ternary compound of bulk formula elements; and
a backing plate bonded to the target blank.

21. A chalcogenide PVD component comprising:
a rigid mass exhibiting a bulk formula including three or more elements, at least one element being from the group consisting of S, Se, and Te, and containing a homogeneous mixture of a compound of two or more bulk formula elements and one or more elemental constituent of the bulk formula and/or one or more additional compound of two or more bulk formula elements, the mass exhibiting a maximum feature size of 500 μm or less; and
the mixture containing each bulk formula element and exhibiting a uniform composition with less than 10% difference in atomic compositions from feature to feature.

22. The component of claim 21 wherein the mass is a single piece and has a PVD exposure area of greater than 150 square in.

23. A chalcogenide PVD component comprising:
a single-piece PVD target blank exhibiting a bulk formula including three or more elements, at least one element being from the group consisting of S, Se, and Te, and containing a homogeneous mixture of two or more different binary or ternary compounds of bulk formula elements, the blank having a PVD exposure area of greater than 150 square in., the blank exhibiting a maximum feature size of 50 μm or less, 100 vol % of the blank having a crystalline microstructure, and the blank exhibiting stability down to a vacuum pressure of 1×10⁻⁵ Torr or less;
the mixture consisting of each bulk formula element and exhibiting a uniform composition with less than 10% difference in atomic compositions from feature to feature; and
a backing plate bonded to the target blank.
